(19) United States
(12) Patent Application Publication
(10) Pub. No.: US 2026/0271227 A1
(43) Pub. Date: Sep. 10, 2026

(54) LIQUID COOLING HEAT DISSIPATION ASSEMBLY AND SERVER DEVICE INCLUDING THE SAME

(71) Applicants: INVENTEC (PUDONG) TECHNOLOGY CORPORATION, Shanghai (CN); INVENTEC CORPORATION, Taipei City (TW)

(72) Inventors: Kunlong ZHANG, Shanghai (CN); Zhao GENG, Shanghai City (CN)

(73) Assignees: INVENTEC (PUDONG) TECHNOLOGY CORPORATION, Shanghai (CN); INVENTEC CORPORATION, Taipei City (TW)

(21) Appl. No.: 19/215,753

(22) Filed: May 22, 2025

(30) Foreign Application Priority Data
Mar. 7, 2025 (CN) 202510273722.2

(51) Int. Cl. H05K 7/20

(52) U.S. Cl. CPC H05K 7/20272; H05K 7/20254; H05K 7/20263; H05K 7/2039; H05K 7/20772

(57) ABSTRACT

A liquid cooling heat dissipation assembly is configured for cooling a central processing unit, a plurality of voltage regulators and one or more dual in-line memory modules. The liquid cooling heat dissipation assembly includes at least one processor cold plate, at least one inlet distribution manifold and at least one memory cold plate. The processor cold plate is in thermal contact with the central processing unit and for a coolant to flow through. The inlet distribution manifold is in fluid communication with the processor cold plate and in thermal contact with the voltage regulators. The memory cold plate is in fluid communication with the inlet distribution manifold and in thermal contact with the dual in-line memory modules. The processor cold plate, the inlet distribution manifold and the memory cold plate collectively form a cooling loop, allowing the coolant to sequentially flow therethrough within the cooling loop.

### CROSS-REFERENCE TO RELATED APPLICATIONS

This non-provisional application claims priority under 35 U.S.C. § 119(a) on Patent Application No(s). 202510273722.2 filed in China, on Mar. 7, 2025, the entire contents of which are hereby incorporated by reference.

### BACKGROUND OF THE INVENTION

### Technical Field of the Invention

The invention relates to a liquid cooling heat dissipation assembly and a server device including the same, especially to an integrated liquid cooling heat dissipation assembly and a server device including the same.

### Description of the Related Art

With the continuous advancement of artificial intelligence (AI), AI products have emerged in rapid succession, leading to an increasing market demand for computing power. To enhance computing speed, server performance must be correspondingly improved. However, the computational capability of high-performance servers is typically accompanied by higher power consumption, necessitating more efficient cooling solutions for high-performance chips.

In recent years, countries worldwide have been actively promoting energy conservation and carbon reduction, bringing the energy consumption of data centers into sharp focus. Conventional air-cooled servers primarily rely on high-speed fans to cool internal heat-generating components. However, this cooling method is characterized by high energy consumption, excessive noise, and low cooling efficiency. In conventional servers, the central processing unit (CPU) and the dual in-line memory module (DIMM) are typically the primary high-power heat-generating components. Moreover, in high-power CPU environments, power modules responsible for stable power delivery, such as voltage regulators (VRs), also generate significant heat.

Therefore, effectively addressing the cooling challenges of CPUs, DIMMs and power modules has become a key research focus in server cooling technology.

### SUMMARY OF THE INVENTION

The invention provides a liquid cooling heat dissipation assembly and a server device including the same capable of addressing the issues of high energy consumption, excessive noise and low cooling efficiency in conventional air-cooled servers.

One embodiment of the invention provides a liquid cooling heat dissipation assembly configured for cooling a central processing unit, a plurality of voltage regulators and one or more dual in-line memory modules. The liquid cooling heat dissipation assembly includes at least one processor cold plate, at least one inlet distribution manifold and at least one memory cold plate. The processor cold plate is configured to be in thermal contact with the central processing unit and for a coolant to flow through. The inlet distribution manifold is in fluid communication with the processor cold plate and configured to be in thermal contact with the voltage regulators. The memory cold plate is in fluid communication with the inlet distribution manifold and configured to be in thermal contact with the dual in-line memory modules. Additionally, the processor cold plate, the inlet distribution manifold and the memory cold plate collectively form a cooling loop, allowing the coolant to sequentially flow through the processor cold plate, the inlet distribution manifold and the memory cold plate within the cooling loop.

One embodiment of the invention provides a server device including a motherboard, a central processing unit, a plurality of voltage regulators, one or more dual in-line memory modules and a liquid cooling heat dissipation assembly. The central processing unit, the voltage regulators and the dual in-line memory modules are disposed on the motherboard. The liquid cooling heat dissipation assembly includes at least one processor cold plate, at least one inlet distribution manifold and at least one memory cold plate. The processor cold plate is in thermal contact with the central processing unit and configured for a coolant to flow through. The inlet distribution manifold is in fluid communication with the processor cold plate and is in thermal contact with the voltage regulators. The memory cold plate is in fluid communication with the inlet distribution manifold and is in thermal contact with the dual in-line memory modules. Additionally, the processor cold plate, the inlet distribution manifold and the memory cold plate collectively form a cooling loop, allowing the coolant to sequentially flow through the processor cold plate, the inlet distribution manifold and the memory cold plate within the cooling loop.

According to the liquid cooling heat dissipation assembly and the server device as discussed in the above embodiments, through the design of the integrated liquid cooling heat dissipation assembly, simultaneous and efficient heat dissipation can be achieved for the central processing unit, voltage regulators and dual in-line memory modules. Moreover, the processor cold plate is in thermal contact with the central processing unit, the memory cold plate is in thermal contact with the dual in-line memory modules, and the inlet distribution manifold is in thermal contact with the voltage regulators. A cooling loop is formed among the processor cold plate, the inlet distribution manifold and the memory cold plate, allowing the coolant to sequentially flow through the processor cold plate, the inlet distribution manifold and the memory cold plate, which enables simultaneous and efficient heat dissipation for the central processing unit, the voltage regulators, and the dual in-line memory module.

### BRIEF DESCRIPTION OF THE DRAWINGS

The invention will become more fully understood from the detailed description given hereinbelow and the accompanying drawings which are given by way of illustration only and thus are not limitative of the invention and wherein:

FIG. 1 is a partial perspective view of a server device according to one embodiment of the invention;

FIG. 2 is an exploded view of the server device as shown in FIG. 1; and

FIG. 3 is a top view of the server device as shown in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have its own meanings and can be comprehended by those skilled in the art, unless the terms are additionally defined in the invention. That is, the terms used in the following paragraphs should be read on the meaning commonly used in the related fields and will not be overly explained, unless the terms have a specific meaning in the invention.

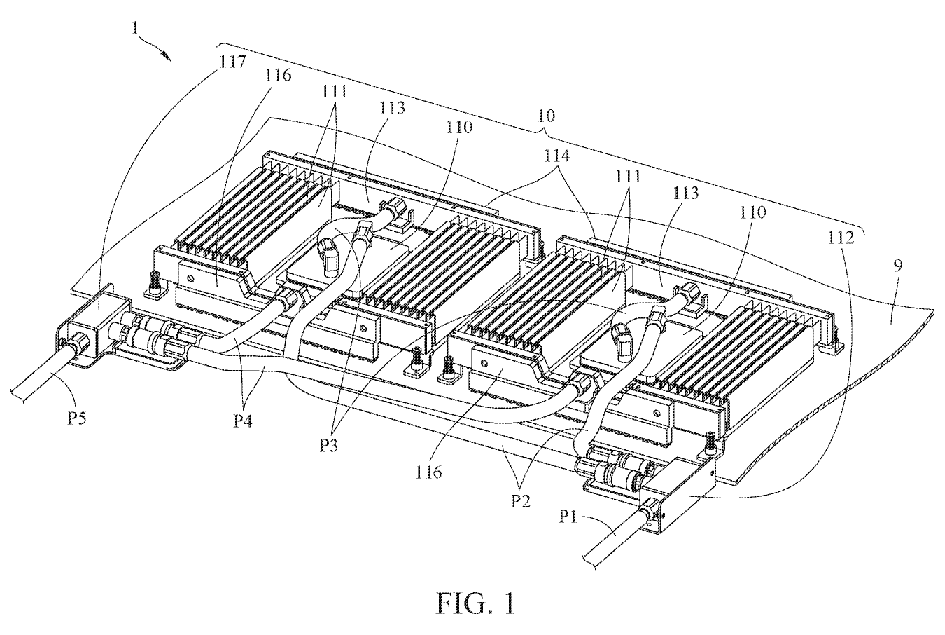

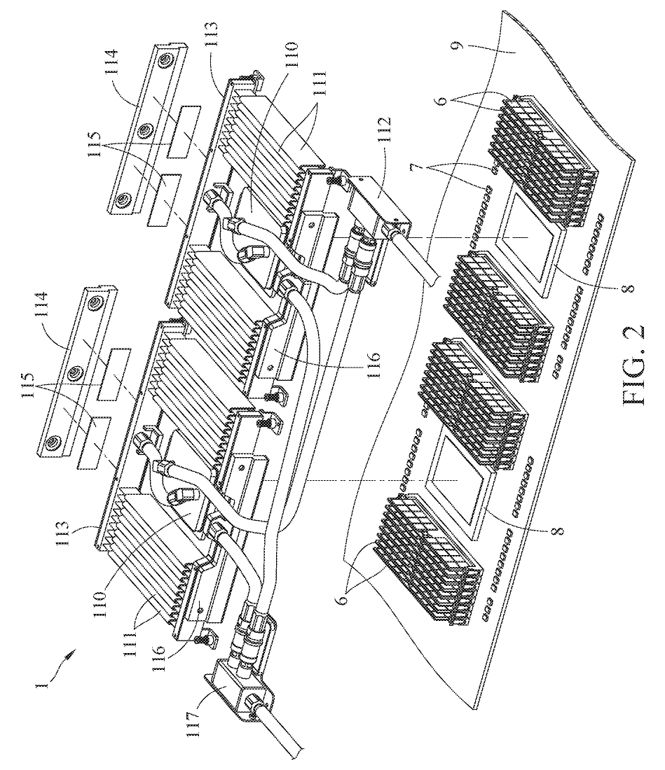

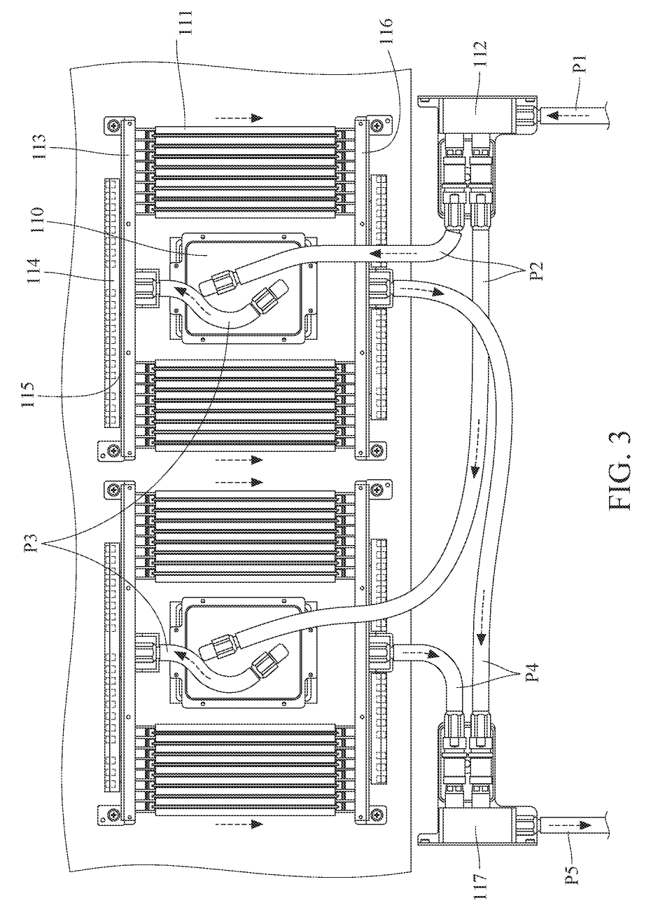

Referring to FIG. 1 to FIG. 3, FIG. 1 is a partial perspective view of a server device according to one embodiment of the invention, FIG. 2 is an exploded view of the server device as shown in FIG. 1, and FIG. 3 is a top view of the server device as shown in FIG. 1.

In this embodiment, a server device 1 is provided. The server device 1 includes a motherboard 9, two central processing units 8, a plurality of voltage regulators 7, a plurality of dual in-line memory modules 6 and a liquid cooling heat dissipation assembly 10. The central processing units 8, the voltage regulators 7 and the dual in-line memory modules 6 are disposed on the motherboard 9. The liquid cooling heat dissipation assembly 10 is configured for cooling the central processing units 8, the voltage regulators 7 and the dual in-line memory modules 6.

The liquid cooling heat dissipation assembly 10 can include two processor cold plates 110, a plurality of memory cold plates 111, a splitter manifold 112, two inlet distribution manifolds 113, two heat dissipation plates 114, a plurality of thermal pads 115, two outlet collection manifolds 116 and a merger manifold 117.

The processor cold plates 110 are respectively in thermal contact with the central processing units 8 and are configured for a coolant to flow through, and the memory cold plates 111 are in thermal contact with the dual in-line memory modules 6 and are configured for the coolant to flow through.

The splitter manifold 112 is in fluid communication with a coolant distribution unit (CDU) (not shown) via a main inlet pipe P1 and is in fluid communication with the two processor cold plates 110 through two splitter pipes P2 in a parallel connection design. The splitter manifold 112 is configured to split the coolant flowing in from the main inlet pipe P1 and direct the coolant to the two processor cold plates 110 via the two splitter pipes P2, thereby enabling efficient heat dissipation for the central processing units 8. Said coolant distribution unit may, for example, include a heat exchanger configured for cooling the coolant.

Each of the two processor cold plates 110 is in fluid communication with the inlet distribution manifold 113 corresponding thereto via a connection pipe P3, allowing the coolant to flow from the processor cold plates 110 into the inlet distribution manifolds 113. Moreover, the two inlet distribution manifolds 113 are in thermal contact with some of the voltage regulators 7, thereby enabling efficient heat dissipation for the voltage regulators 7.

In this embodiment, the two inlet distribution manifolds 113 are in thermal contact with the voltage regulators 7 via the heat dissipation plates 114 and the thermal pads 115. Specifically, the two heat dissipation plates 114 are respectively in thermal contact with the two inlet distribution manifolds 113 and also in thermal contact with the voltage regulators 7. Additionally, the thermal pads 115 are provided between each corresponding one of the inlet distribution manifold 113 and the heat dissipation plate 114, and the thermal pads 115 are thermally coupled to both the inlet distribution manifolds 113 and the heat dissipation plates 114. Through this configuration, the heat generated by the voltage regulators 7 is transferred via thermal conduction through the thermal pads 115 and the heat dissipation plates 114 to the inlet distribution manifolds 113, and the coolant flowing through the inlet distribution manifolds 113 then carries the heat away, thereby achieving efficient heat dissipation for the voltage regulators 7. However, the heat dissipation plate and the thermal pad are optional, and the invention is not limited thereto.

The inlet distribution manifolds 113 and the outlet collection manifolds 116 are respectively located at opposite ends of the memory cold plates 111 and are in fluid communication with the memory cold plates 111. In other words, the memory cold plates 111 are connected and located between the inlet distribution manifolds 113 and the outlet collection manifolds 116. Moreover, the inlet distribution manifolds 113 are configured to split the coolant flowing in from the connection pipes P3 and direct the coolant to the memory cold plates 111, thereby enabling efficient heat dissipation for the dual in-line memory modules 6 through the memory cold plates 111.

The outlet collection manifolds 116 are configured to collect the coolant from the memory cold plates 111 and are in fluid communication with the merger manifold 117 via two collection pipes P4. The merger manifold 117 is configured to merge the coolant flowing in from the two collection pipes P4 and is in fluid communication with the coolant distribution unit via a main outlet pipe P5, directing the coolant from the outlet collection manifolds 116 to the coolant distribution unit. Moreover, the heat exchanger of the coolant distribution unit is capable of cooling the coolant.

Through the above configuration, a cooling loop can be formed among the processor cold plates 110, the inlet distribution manifolds 113 and the memory cold plates 111, allowing the coolant to sequentially flow through the processor cold plates 110, the inlet distribution manifolds 113 and the memory cold plates 111 within the cooling loop, which enables simultaneous and efficient heat dissipation for the central processing units 8, the voltage regulators 7 and the dual in-line memory modules 6.

In this embodiment, the outlet collection manifolds 116 may also be in thermal contact with some of the voltage regulators 7 to achieve efficient heat dissipation for the voltage regulators 7. Furthermore, the outlet collection manifolds 116 may also be in thermal contact with the voltage regulators 7 through heat dissipation plates and thermal pads. Through this configuration, the heat generated by the voltage regulators 7 can be transferred via thermal conduction through the thermal pads and the heat dissipation plates to the outlet collection manifolds 116, and the heat is then carried away by the coolant flowing through the outlet collection manifolds 116, thereby achieving efficient heat dissipation for the voltage regulators 7. Therefore, as shown in FIG. 3, the processor cold plates 110, the inlet distribution manifolds 113, the memory cold plates 111 and the outlet collection manifolds 116 can collectively form the cooling loop, allowing the coolant to sequentially flow through the processor cold plates 110, the inlet distribution manifolds 113, the memory cold plates 111 and the outlet collection manifolds 116 within the cooling loop, which enables simultaneous and efficient heat dissipation for the central processing units 8, the voltage regulators 7 and the dual in-line memory modules 6.

In this embodiment, the main inlet pipe P1 and the main outlet pipe P5 may, for example, be polytetrafluoroethylene (PTFE) corrugated pipes, but the invention is not limited thereto. Additionally, the main inlet pipe P1 and the main outlet pipe P5 may be connected to the coolant distribution unit via UQD04 quick connectors (not numbered).

In this embodiment, the splitter manifold 112 and the merger manifold 117 may, for example, be stainless steel manifolds, but the invention is not limited thereto. Additionally, the splitter pipes P2 may be connected to the splitter manifold 112 via UQD02 quick connectors, and the collection pipes P4 may be connected to the merger manifold 117 via UQD02 quick connectors (not numbered). Moreover, each quick connector assembly consists of two parts, namely a male end and a female end. The male end includes a spring washer and may feature a trapezoidal boss at the connection point, which provides reinforcement and fixation. The female end consists of a main body, a hose nozzle, and a quick-tightening nut. The main body and the hose nozzle are securely connected through a boss structure, ensuring stability. The hose nozzle is provided with a barbed structure, enhancing connection strength. Multiple threads are provided at the rear of the barbed section, allowing the quick-tightening nut to secure the hose onto the hose nozzle, thereby simplifying installation. Through this design, the quick connector features a simple structure, making it easy to disassemble and maintain.

In this embodiment, the processor cold plates 110 and the heat dissipation plates 114 may, for example, be made of copper, but the invention is not limited thereto. Additionally, the memory cold plates 111 may, for example, be made of stainless steel, but the invention is not limited thereto.

In this embodiment, the pipes may be connected to the cold plates and manifolds using a barbed fitting connection means. For example, the main inlet pipe P1 may be connected to the splitter manifold 112 via a barbed fitting, and the processor cold plate 110 may also be connected to the splitter pipe P2 using a barbed fitting. Said barbed fitting may, for example, be a nut-secured type. The hose nozzle of the barbed fitting is designed with a three-tiered barb, providing a large contact area, high load-bearing capacity, and strong connection strength. Under repeated load conditions, it remains secure without displacement or loosening. The multiple threads at the rear of the barbed section work in conjunction with a quick-tightening nut to secure the hose firmly, enhancing stability and fastening strength.

The present invention is not limited to a specific number of processor cold plates, memory cold plates, inlet distribution manifolds, or outlet collection manifolds. In different embodiments of the invention, the number of these components can be adjusted to one or more based on actual design requirements. For example, the number of processor cold plates may be adjusted according to the number of central processing units that require cooling.

According to the liquid cooling heat dissipation assembly and the server device as described in the above embodiment, through the design of the integrated liquid cooling heat dissipation assembly, simultaneous and efficient heat dissipation can be achieved for the central processing unit, voltage regulators and dual in-line memory modules. Moreover, the processor cold plate is in thermal contact with the central processing unit, the memory cold plate is in thermal contact with the dual in-line memory modules, and the inlet distribution manifold and the outlet collection manifold are in thermal contact with the voltage regulators. A cooling loop is formed among the processor cold plate, the inlet distribution manifold, the memory cold plate and the outlet collection manifold, allowing the coolant to sequentially flow through the processor cold plate, the inlet distribution manifold, the memory cold plate and the outlet collection manifold, which enables simultaneous and efficient heat dissipation for the central processing unit, the voltage regulators, and the dual in-line memory module.

Furthermore, compared to conventional air-cooled servers, the liquid cooling heat dissipation assembly and the server device including the same, as disclosed in the present invention, adopt a liquid cooling solution with thermal conductivity 15 to 25 times higher than that of air cooling solutions, which enables more efficient heat dissipation for higher heat flux densities, making it suitable for high-power central processing units, dual in-line memory modules, and voltage regulators, and offering a greater stable performance and a longer lifespan.

Moreover, compared to conventional air-cooled servers, the liquid cooling heat dissipation assembly and the server device including the same, as disclosed in the present invention, feature a more compact liquid cooling system design. Since heat dissipation is achieved through liquid flow, it is not constrained by space limitations and provides superior cooling performance.

Furthermore, in conventional servers, where only air cooling is used, the central processing unit, dual in-line memory modules, and voltage regulators are often thermal bottlenecks and frequently influence fan speed control, making them critical points for thermal management risks. The liquid cooling heat dissipation assembly and the server device including the same, as disclosed in the present invention, feature a liquid cooling design that effectively covers most heat sources on the motherboard, significantly addressing this issue and thereby reducing the power consumption of system fans. Additionally, compared to liquid cooling solutions that employ a cold plate only on the central processing unit, the liquid cooling heat dissipation assembly and the server device including the same as disclosed in the present invention can reduce fan power consumption by up to 20%.

During the simulation testing of the liquid cooling heat dissipation assembly and the server device as described in the above embodiment, system simulations were conducted under the conditions of coolant inlet temperature of 40°C with flow rates of 1.2 L/min and 1.6 L/min and coolant inlet temperature of 47°C with flow rates of 1.6 L/min and 2.0 L/min. Moreover, in these simulations, the power consumption of the central processing unit (CPU) is 600W, the power consumption of the dual in-line memory module (DIMM) is 16.08W, and the power consumption of the voltage regulator (VR) is 98.142W. The simulation results showed that the maximum temperature of the central processing units ranged from 63.1°C to 70.1°C, all below the specified limit of 72°C; the temperature of the dual in-line memory modules ranged from 61.7°C to 67.7°C, all below the specified limit of 75°Cp; and the temperature of the voltage regulators ranged from 65.4°C to 72.4°C, also below the specified limit of 90°C. These results confirm that the simulation meets the specification requirements of all components and provides sufficient thermal margin.

It will be apparent to those skilled in the art that various modifications and variations can be made to the invention. It is intended that the specification and examples be considered as exemplary embodiments only, with a scope of the invention being indicated by the following claims and their equivalents.

What is claimed is:

1. A liquid cooling heat dissipation assembly configured for cooling a central processing unit, a plurality of voltage regulators and one or more dual in-line memory modules, and the liquid cooling heat dissipation assembly comprising:
at least one processor cold plate configured to be in thermal contact with the central processing unit and for a coolant to flow through;
at least one inlet distribution manifold in fluid communication with the at least one processor cold plate and configured to be in thermal contact with the plurality of voltage regulators; and
at least one memory cold plate in fluid communication with the at least one inlet distribution manifold and configured to be in thermal contact with the one or more dual in-line memory modules;
wherein the at least one processor cold plate, the at least one inlet distribution manifold and the at least one memory cold plate collectively form a cooling loop, allowing the coolant to sequentially flow through the at least one processor cold plate, the at least one inlet distribution manifold and the at least one memory cold plate within the cooling loop.

2. The liquid cooling heat dissipation assembly according to claim 1, further comprising at least one heat dissipation plate configured to be in thermal contact with the at least one inlet distribution manifold and the plurality of voltage regulators.

3. The liquid cooling heat dissipation assembly according to claim 2, further comprising at least one thermal pad thermally coupled and disposed between the at least one inlet distribution manifold and the at least one heat dissipation plate.

4. The liquid cooling heat dissipation assembly according to claim 1, further comprising at least one outlet collection manifold, wherein the at least one outlet collection manifold and the at least one inlet distribution manifold are respectively located at opposite ends of the at least one memory cold plate and are in fluid communication with the at least one memory cold plate, the at least one outlet collection manifold is configured to be in thermal contact with the plurality of voltage regulators, and the at least one processor cold plate, the at least one inlet distribution manifold, the at least one memory cold plate and the at least one outlet collection manifold collectively form the cooling loop, allowing the coolant to sequentially flow through the at least one processor cold plate, the at least one inlet distribution manifold, the at least one memory cold plate and the at least one outlet collection manifold within the cooling loop.

5. The liquid cooling heat dissipation assembly according to claim 4, further comprising a splitter manifold and a merger manifold, wherein the at least one processor cold plate comprises two processor cold plates, the at least one memory cold plate comprises a plurality of memory cold plates, the at least one inlet distribution manifold comprises two inlet distribution manifolds, and the at least one outlet collection manifold comprises two outlet collection manifolds;
wherein the splitter manifold is configured to be in fluid communication with a heat exchanger via a main inlet pipe, the splitter manifold is in fluid communication with the two processor cold plates through two splitter pipes, the two processor cold plates are respectively in fluid communication with the two inlet distribution manifolds via two connection pipes, the plurality of memory cold plates are connected and located between the two inlet distribution manifolds and the two outlet collection manifolds, the two outlet collection manifolds are respectively in fluid communication with the merger manifold via two collection pipes, and the merger manifold is configured to be in fluid communication with the heat exchanger through a main outlet pipe.

6. A server device comprising:
a motherboard;
a central processing unit disposed on the motherboard;
a plurality of voltage regulators disposed on the motherboard;
one or more dual in-line memory modules disposed on the motherboard; and
a liquid cooling heat dissipation assembly comprising:
at least one processor cold plate in thermal contact with the central processing unit and configured for a coolant to flow through;
at least one inlet distribution manifold in fluid communication with the at least one processor cold plate and in thermal contact with the plurality of voltage regulators; and
at least one memory cold plate in fluid communication with the at least one inlet distribution manifold and in thermal contact with the one or more dual in-line memory modules;
wherein the at least one processor cold plate, the at least one inlet distribution manifold and the at least one memory cold plate collectively form a cooling loop, allowing the coolant to sequentially flow through the at least one processor cold plate, the at least one inlet distribution manifold and the at least one memory cold plate within the cooling loop.

7. The server device according to claim 6, wherein the liquid cooling heat dissipation assembly further comprises at least one heat dissipation plate, and the at least one heat dissipation plate is in thermal contact with the at least one inlet distribution manifold and the plurality of voltage regulators.

8. The server device according to claim 7, wherein the liquid cooling heat dissipation assembly further comprises at least one thermal pad thermally coupled and disposed between the at least one inlet distribution manifold and the at least one heat dissipation plate.

9. The server device according to claim 6, wherein the liquid cooling heat dissipation assembly further comprises at least one outlet collection manifold, the at least one outlet collection manifold and the at least one inlet distribution manifold are respectively located at opposite ends of the at least one memory cold plate and are in fluid communication with the at least one memory cold plate, the at least one outlet collection manifold is in thermal contact with the plurality of voltage regulators, and the at least one processor cold plate, the at least one inlet distribution manifold, the at least one memory cold plate and the at least one outlet collection manifold collectively form the cooling loop, allowing the coolant to sequentially flow through the at least one processor cold plate, the at least one inlet distribution manifold, the at least one memory cold plate and the at least one outlet collection manifold within the cooling loop.

10. The server device according to claim 9, wherein the liquid cooling heat dissipation assembly further comprises a splitter manifold and a merger manifold, the at least one processor cold plate comprises two processor cold plates, the at least one memory cold plate comprises a plurality of memory cold plates, the at least one inlet distribution manifold comprises two inlet distribution manifolds, and the at least one outlet collection manifold comprises two outlet collection manifolds;
wherein the splitter manifold is configured to be in fluid communication with a heat exchanger via a main inlet pipe, the splitter manifold is in fluid communication with the two processor cold plates through two splitter pipes, the two processor cold plates are respectively in fluid communication with the two inlet distribution manifolds via two connection pipes, the plurality of memory cold plates are connected and located between the two inlet distribution manifolds and the two outlet collection manifolds, the two outlet collection manifolds are respectively in fluid communication with the merger manifold via two collection pipes, and the merger manifold is in fluid communication with the heat exchanger through a main outlet pipe.
